(19) United States
(12) Patent Application Publication
(10) Pub. No.: US 2026/0318579 A1
(43) Pub. Date: Oct. 15, 2026

(54) INTERNAL REFRIGERATION APPARATUS AND REFRIGERATION STORAGE

(71) Applicant: DAIKIN INDUSTRIES, LTD., Osaka (JP)

(72) Inventors: Kazuhiro SUZUKI, Osaka (JP); Makoto IKEMIYA, Osaka (JP)

(73) Assignee: DAIKIN INDUSTRIES, LTD., Osaka (JP)

(21) Appl. No.: 19/464,642

(22) Filed: Jan. 30, 2026

Related U.S. Application Data
(63) Continuation of application No. PCT/JP2024/026198, filed on Jul. 22, 2024.

(30) Foreign Application Priority Data
Aug. 1, 2023 (JP) 2023-125744

(51) Int. Cl. F25B 49/02; G01M 3/04; G01M 3/26; G01R 19/165

(52) U.S. Cl. CPC F25B 49/02; G01M 3/04; G01M 3/26; G01R 19/1659; F25B 2500/222

(57) ABSTRACT

An internal refrigeration apparatus that cools an internal space includes: a refrigerant circuit that performs a refrigeration cycle; a refrigerant sensor that detects a refrigerant leaking into the internal space; a first sensor that detects an index different from a refrigerant; and circuitry that is configured to determine refrigerant leakage in the internal space based on detection results of the refrigerant sensor and the first sensor.

### CROSS-REFERENCE TO RELATED APPLICATIONS

The present application claims priority to International Application No. PCT/JP2024/026198, filed Jul. 22, 2024, and Japanese Patent Application No. 2023-125744, filed Aug. 1, 2023, the entire content of each of which is incorporated by reference herein in its entirety for all purposes.

### TECHNICAL FIELD

The present disclosure relates to an internal refrigeration apparatus and refrigeration storage.

### BACKGROUND ART

The internal refrigeration apparatus disclosed in Patent Literature 1 includes a refrigerant sensor provided in a container. The refrigerant sensor detects refrigerant gas leaking from a refrigerant circuit into the container.

### CITATION LIST

### Patent Document

Patent Literature 1: JP 2020-101327 A

### SUMMARY

In a refrigeration storage such as the container in Patent Literature 1, when a miscellaneous gas is generated in the internal space, the refrigerant sensor may erroneously detect the miscellaneous gas as the refrigerant gas.

An object of the present disclosure is to provide an internal refrigeration apparatus that suppresses erroneous detection of a refrigerant leaking into the refrigeration storage.

A first aspect
provides an internal refrigeration apparatus configured to cool an internal space (S) using a refrigerant circuit (R) configured to perform a refrigeration cycle, the internal refrigeration apparatus including:
a refrigerant sensor (50) configured to detect a refrigerant leaking into the internal space (S);
a first sensor (51) configured to detect an index different from a refrigerant; and
a control unit or circuitry (100) configured to determine refrigerant leakage in the internal space (S) based on detection results of the refrigerant sensor (50) and the first sensor (51).

With only the refrigerant sensor (50), for example, there is a risk of erroneously detecting the miscellaneous gas and the refrigerant gas that are generated in the internal space (S). On the other hand, in the first aspect, in addition to the detection result of the refrigerant sensor (50), the detection result of the first sensor (51) is used for the determination of the refrigerant leakage. By determining that the change in the internal environment detected by the first sensor (51) is caused by the refrigerant gas, it is possible to suppress erroneous detection of refrigerant leakage in the internal space (S).

In a second aspect according to the first aspect,
the first sensor (51) detects a gas component in the internal space (S), and
in a case where the refrigerant sensor (50) detects refrigerant leakage and the first sensor (51) detects that a concentration of a gas component in the internal space (S) or a degree of a change in the concentration is out of a predetermined range, the circuitry (100) is configured to determine refrigerant leakage in the internal space (S).

In the second aspect, the first sensor (51) can be used not only for detection of a gas component in the internal space (S) but also for determination of refrigerant leakage.

In a third aspect according to the second aspect,
the first sensor (51) detects humidity, oxygen, or carbon dioxide in the internal space (S).

In the third aspect, a miscellaneous gas such as an ethylene gas is unlikely to be erroneously detected by a type of sensor used for detecting humidity, oxygen, or carbon dioxide. By using such a sensor and the refrigerant sensor (50) for refrigerant leakage determination, reliability of refrigerant leakage determination can be improved. In addition, such a sensor is already installed in the internal space (S), and there is no need to newly provide a sensor.

In a fourth aspect according to the first aspect,
the first sensor (51) detects pressure of gas in the internal space (S), and
in a case where the refrigerant sensor (50) detects refrigerant leakage and the first sensor (51) detects that pressure of gas in the internal space (S) or a degree of a change in the pressure is out of a predetermined range, the circuitry (100) is configured to determine refrigerant leakage in the internal space (S).

In the fourth aspect, when the refrigerant leaks, the pressure of the gas in the internal space (S) increases. The change in the pressure of the gas in the internal space (S) can be used to determine refrigerant leakage.

A fifth aspect according to the first aspect,
provides the internal refrigeration apparatus further including an internal fan (30) configured to circulate air in the internal space (S),
in which the first sensor (51) detects a current value of a motor (30a) configured to drive the internal fan (30), and
in a case where the refrigerant sensor (50) detects refrigerant leakage and the first sensor (51) detects that a current value of the motor (30a) or a degree of a change in the current value is out of a predetermined range, the circuitry (100) is configured to determine refrigerant leakage in the internal space (S).

In the fifth aspect, when the refrigerant leaks into the internal space (S), the density of the gas composition in the internal space (S) increases. Therefore, the operation load of the internal fan (30) increases, and the value of the current flowing through the motor (30a) increases. This change in the current value can be used to determine refrigerant leakage.

In a sixth aspect according to the first aspect,
the first sensor (51) detects pressure or temperature of a refrigerant flowing through the refrigerant circuit (R), and
in a case where the first sensor (51) detects refrigerant leakage and the first sensor (51) detects that an index indicating pressure or temperature of the refrigerant flowing through the refrigerant circuit (R) or a degree of a change in the index is out of a predetermined range, the circuitry (100) is configured to determine refrigerant leakage in the internal space (S).

In the sixth aspect, when the refrigerant leaks from the refrigerant circuit (R), the pressure and temperature of the refrigerant in the refrigerant circuit (R) change. The change in refrigerant pressure or refrigerant temperature in the refrigerant circuit (R) can be used for determination of refrigerant leakage.

A seventh aspect provides a refrigeration storage including the internal refrigeration apparatus according to any one of the first to sixth aspects.

### BRIEF DESCRIPTION OF THE DRAWINGS

FIG. 1 is a perspective view of an internal refrigeration apparatus according to an embodiment as viewed from a front.

FIG. 2 is a longitudinal sectional view of the internal refrigeration apparatus.

FIG. 3 is a piping system diagram of the internal refrigeration apparatus.

FIG. 4 is a block diagram illustrating a relationship between circuitry of the internal refrigeration apparatus and other instruments.

FIG. 5 is a flowchart illustrating a refrigerant leakage determination operation by circuitry.

FIG. 6 is a table illustrating an example of a relationship between a refrigerant leakage amount and relative humidity.

FIG. 7 is a flowchart illustrating a refrigerant leakage determination operation by circuitry according to a fourth modification.

### DESCRIPTION OF EMBODIMENTS

Embodiments of the present invention will be described hereinafter with reference to the drawings. Note that the following embodiments are essentially preferred examples, and are not intended to limit the scope of the present invention, matters to which the present invention is applicable, or the usage of the present invention. In addition, configurations of the respective embodiments, modifications, other examples, and the like described below can be combined or partially replaced within the scope in which the present invention can be implemented.

### (1) Overall Configuration of Container

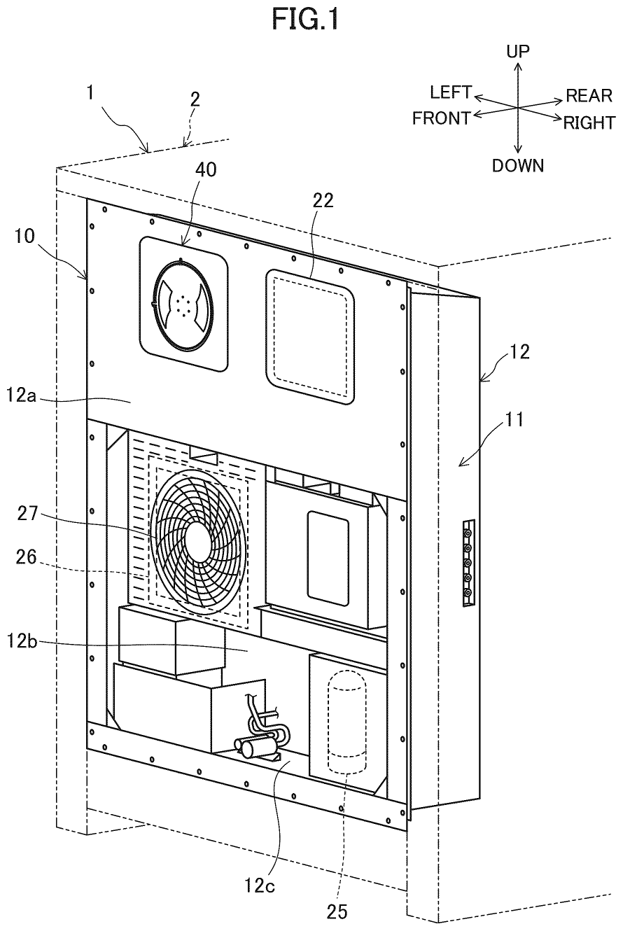

As illustrated in FIG. 1, an internal refrigeration apparatus (10) is applied to a container (1). The container (1) is an example of a refrigeration storage (1). The container (1) is used for marine transportation. The container (1) is a freezing container that cools air inside the container (1).

An overall configuration of the container (1) of the present embodiment will be described with reference to FIGS. 1 to 3. Note that, in the following description, phrases relating to “front”, “back”, “left”, “right ”, “up”, and “down” are based on directions indicated by arrows in FIG. 1.

The container (1) includes a container main body (2) and the internal refrigeration apparatus (10). An internal space (S) of the container main body (2) is partitioned into a housing space (3) and an air passage (19). The housing space (3) and the air passage (19) communicate with each other so that air circulates therethrough. Storage objects such as foods and plants are stored in the housing space (3). The internal refrigeration apparatus (10) cools air in the housing space (3). A front opening (4) is formed on a front surface of the container main body (2). The internal refrigeration apparatus (10) is attached to the container main body (2) so as to close the front opening (4) of the container main body (2).

### (2) Internal Refrigeration Apparatus

The internal refrigeration apparatus (10) includes a casing (11). The casing (11) constitutes a lid of the front opening (4) of the container main body (2). The casing (11) includes a casing main body (12) and a partition plate (13). The casing main body (12) partitions an external space (5), which is an outer space of the container main body (2), and the housing space (3). The partition plate (13) is located on the back side (rear side) of the casing (11).

The internal refrigeration apparatus (10) includes a refrigerant circuit (R) that performs a refrigeration cycle. The internal refrigeration apparatus (10) includes a compressor (25), an external heat exchanger (26), and an external fan (27) as instruments disposed outside the container (1). The internal refrigeration apparatus (10) includes an internal heat exchanger (29) and an internal fan (30) as instruments disposed inside of the container (1).

### (2-1) Casing Main Body

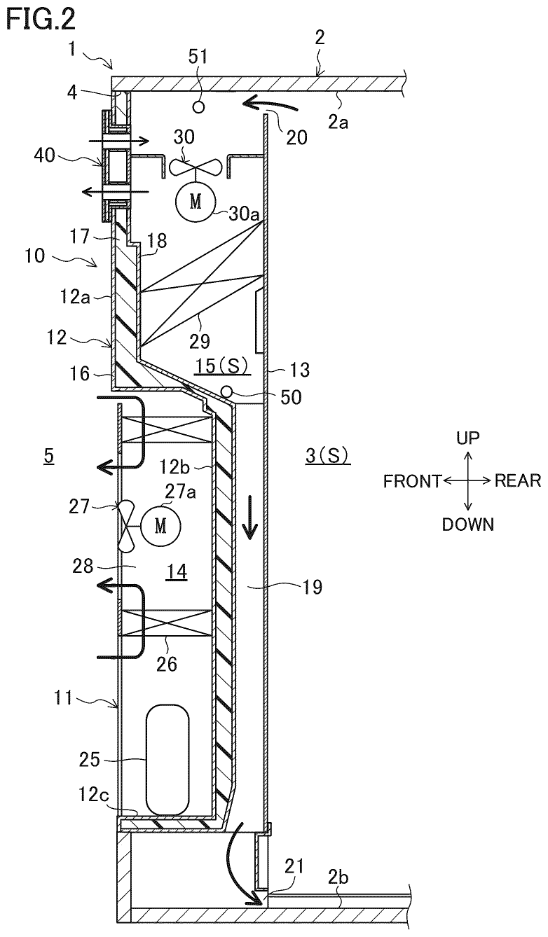

As illustrated in FIG. 2, the casing main body (12) has a flat plate portion (12a) and a concave portion (12b). The flat plate portion (12a) is formed in an upper portion of the casing main body (12) so as to be substantially flush with the front opening (4) of the casing (11). As illustrated in FIG. 1, the flat plate portion (12a) is provided with an inspection window (22) and a ventilator (40). The inspection window (22) is disposed in a right-side portion of the flat plate portion (12a). The ventilator (40) is disposed in a left-side portion of the flat plate portion (12a). The inspection window (22) is a transparent window for checking the inside of the casing main body (12). The ventilator (40) ventilates the housing space (3).

The concave portion (12b) is formed in a lower portion of the casing (11). The concave portion (12b) is recessed rearward from a lower end of the flat plate portion (12a). An external housing space (14) is formed on the front side of the concave portion (12b). An internal housing space (15) is formed above the concave portion (12b) and between the flat plate portion (12a) and the partition plate (13). A lower end of the concave portion (12b) constitutes a bottom plate (12c). The bottom plate (12c) extends across the left and right ends of the casing main body (12).

The casing main body (12) is formed by stacking an external casing (16), a heat insulation layer (17), and an internal casing (18) in a thickness direction (front-rear direction). The external casing (16) faces the external space (5). The internal casing (18) faces the inside of the container (1). As described above, the concave portion (12b) has a side wall (16a) of the external casing (16) and a side wall of the internal casing (18) that are extending in the up-and-down direction. The side wall (16a) of the external casing (16) extending in the up-and-down direction separates the external space (5) from the air passage (19). The heat insulation layer (17) is provided between the external casing (16) and the internal casing (18). The external casing (16) is made of an aluminum material. The internal casing (18) is made of reinforced fiber plastic (FRP). The heat insulation layer (17) is made of foamed resin.

### (2-2) Partition Plate and Air Passage

As illustrated in FIG. 2, the partition plate (13) is a plate-shaped member located behind the concave portion (12b). The partition plate (13) extends in the up-and-down direction so as to be spaced apart from the rear surface of the concave portion (12b) by a predetermined distance. The air passage (19) through which internal air flows is formed between the casing main body (12) and the partition plate (13). An inlet (20) is formed between an upper end of the partition plate (13) and an upper wall (2a) of the container main body (2). The inlet (20) allows the housing space (3) and an inlet end of the air passage (19) to communicate with each other. An outflow port (21) is formed between the lower end of the partition plate (13) and a lower wall (2b) of the container main body (2). The outflow port (21) allows the housing space (3) and the outflow end of the air passage (19) to communicate with each other. In the air passage (19), air flows in the up-and-down direction. Specifically, air flows in the vertical direction in the air passage (19).

### (2-3) Element Component in External Space

The external housing space (14) is provided with the compressor (25), the external heat exchanger (26), and the external fan (27). The compressor (25) is installed on the bottom plate (12c) of the casing (11). The compressor (25) is disposed near a lower portion of the external housing space (14). The compressor (25) is disposed close to the right side of the external housing space (14).

The external fan (27) is located near an upper portion of the external housing space (14). The external fan (27) is driven by an external fan motor (27a). The external fan (27) is a propeller fan. As illustrated in FIG. 2, an external passage (28) through which external air flows is formed on the back side of the external fan (27).

The external heat exchanger (26) is provided at a height position between the external fan (27) and the compressor (25) in the external housing space (14). The external heat exchanger (26) is located in the external passage (28). The external heat exchanger (26) is a fin-and-tube type heat exchanger.

### (2-4) Element Component in Internal Space

The internal heat exchanger (29) and the internal fan (30) are provided in the air passage (19). The internal heat exchanger (29) and the internal fan (30) are provided in the internal housing space (15) that is a part of the air passage (19). The internal heat exchanger (29) is supported by the casing (11) across the casing main body (12) and the partition plate (13). The internal heat exchanger (29) is a fin-and-tube type heat exchanger.

The internal fan (30) circulates air in the internal space (S). The internal fan (30) circulates air in the internal space (S) between the housing space (3) and the air passage (19). The internal fan motor (30a) drives the internal fan (30). The internal fan (30) is a propeller fan.

### (2-5) Refrigerant Circuit

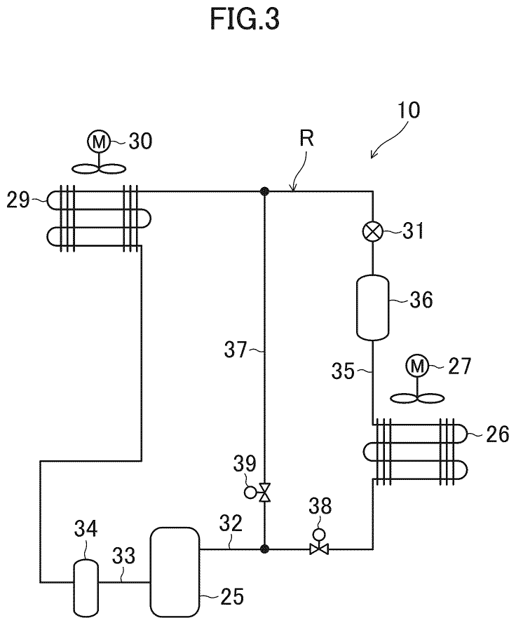

As illustrated in FIG. 3, the internal refrigeration apparatus (10) includes the refrigerant circuit (R). The refrigerant circuit (R) is filled with a refrigerant. The refrigerant circuit (R) performs a vapor compression type refrigeration cycle by circulation of the refrigerant.

As the refrigerant of the present example, 2,3,3,3 tetrafluoropropene (hereinafter, may be referred to as R1234yf refrigerant or R1234yf) is used. In some embodiments, the refrigerant is difluoromethane (R32), 1,3,3,3 tetrafluoropropene (R1234ze). In some embodiments, the refrigerant is a single refrigerant or a mixed refrigerant obtained by mixing other refrigerants. In some embodiments, the mixed refrigerant is a refrigerant including two kinds of 2,3,3,3 tetrafluoropropene (R1234yf) and difluoromethane (R32). In some embodiments, the mixed refrigerant is a refrigerant (R 454C) including two kinds of 78.5 wt % of 2,3,3,3 tetrafluoropropene (R1234yf) and 21.5 wt % of difluoromethane (R32). In some embodiments, the refrigerant is a flammable refrigerant. In some embodiments, the flammable refrigerant is propane (R290), methane (R50), ethane (R170), butane (R600), or isobutane (R600a), which are highly-flammable natural refrigerants. In addition, in some embodiments, the refrigerant is carbon dioxide (CO₂) which is a natural refrigerant.

The refrigerant circuit (R) mainly includes the compressor (25), the external heat exchanger (26), an expansion valve (31), and the internal heat exchanger (29).

The compressor (25) compresses a sucked refrigerant. The compressor (25) discharges the compressed refrigerant. A discharge pipe (32) is connected to a discharge portion of the compressor (25). A suction pipe (33) is connected to a suction portion of the compressor (25). The suction pipe (33) is provided with an accumulator (34). The accumulator (34) is a container that stores liquid refrigerant.

The external heat exchanger (26) exchanges heat between the refrigerant flowing inside thereof and external air. A gas end of the external heat exchanger (26) communicates with the discharge pipe (32). A liquid end of the external heat exchanger (26) is connected to a liquid end of the internal heat exchanger (29) via a liquid pipe (35). The external heat exchanger (26) functions as a radiator (condenser) that radiates heat from the refrigerant to the air.

The expansion valve (31) is provided in the liquid pipe (35). The expansion valve (31) decompresses the high-pressure refrigerant to the low-pressure refrigerant. The expansion valve (31) is an electronic expansion valve whose opening degree is adjustable. A receiver (36) is provided between the external heat exchanger (26) and the expansion valve (31) in the liquid pipe (35). The receiver (36) is a container that stores surplus refrigerant in the refrigerant circuit (R).

The internal heat exchanger (29) exchanges heat between the refrigerant flowing inside and internal air. A gas end of the internal heat exchanger (29) communicates with the suction pipe (33). The internal heat exchanger (29) functions as an evaporator through which a refrigerant absorbs heat from air.

The refrigerant circuit (R) includes a bypass pipe (37). An inflow end of the bypass pipe (37) communicates with the discharge pipe (32), and an outflow end of the bypass pipe (37) communicates with the liquid pipe (35). The bypass pipe (37) feeds refrigerant discharged from the compressor (25) to the internal heat exchanger (29) by bypassing the external heat exchanger (26).

The refrigerant circuit (R) is provided with a first valve (38) and a second valve (39). The first valve (38) is provided between the discharge side of the compressor (25) and the gas end of the external heat exchanger (26), and on the downstream side of the connection portion of the bypass pipe (37). The second valve (39) is provided in the bypass pipe (37). The first valve (38) and the second valve (39) are configured with solenoid valves. In some embodiments, the first valve (38) and the second valve (39) are flow-rate adjustment valves whose opening degree is adjustable.

### (2-6) Operation Motion

The internal refrigeration apparatus (10) performs cooling operation and defrost operation.

During cooling operation, a refrigeration cycle is performed in which a refrigerant compressed by the compressor (25) is condensed by the external heat exchanger (26), decompressed by the expansion valve (31), and evaporated by the internal heat exchanger (29). The air flowing out of the housing space (3) into the air passage (19) is cooled by the internal heat exchanger (29) that functions as an evaporator. The cooled air is sent to the housing space (3) (see the arrow in FIG. 2).

During defrost operation, a refrigerant compressed by the compressor (25) flows through the bypass pipe (37) and flows through the internal heat exchanger (29). The frost on the surface of the internal heat exchanger (29) melts by heat of the refrigerant flowing inside the internal heat exchanger (29).

### (3) Circuitry

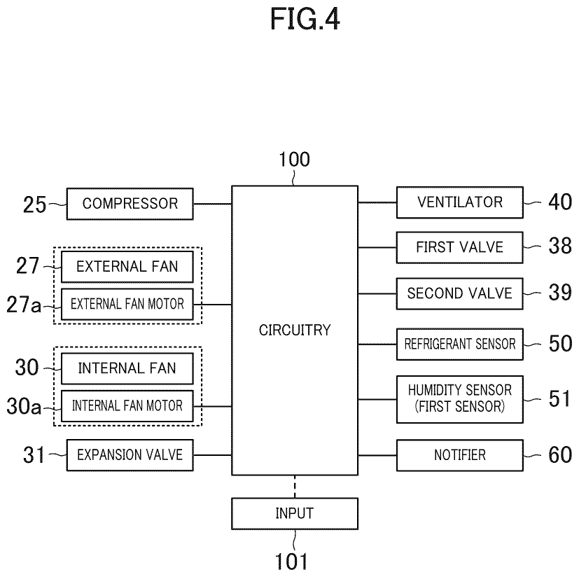

As illustrated in FIG. 4, the internal refrigeration apparatus (10) includes circuitry (100). The circuitry (100) is configured to control the internal refrigeration apparatus (10). The circuitry (100) includes a micro processor, an electric circuit, and/or an electronic circuit. The micro processor includes a central processing unit (CPU), a memory, a communication interface, analog input/output, and/or a contact input/output interface. The memory stores various programs to be executed by the CPU and data used by the programs.

The circuitry (100) is configured to control mechanical elements of the internal refrigeration apparatus (10). As illustrated in FIG. 4, in some embodiments, the target value is a value that can be arbitrarily set by a user of the internal refrigeration apparatus (10) through an operation unit or input (101). The input (101) includes, for example, a touch panel, a remote controller, and a dip switch which are provided in the internal refrigeration apparatus (10). In some embodiments, the input (101) is a communication terminal connected to the internal refrigeration apparatus (10) via a network. The target value is not necessarily set by the user, and for example, in some embodiments, is a value automatically determined by the circuitry (100) according to the operation mode or the operation condition.

### (4) Refrigerant sensor

As illustrated in FIGS. 2 and 4, the internal refrigeration apparatus (10) includes the refrigerant sensor (50). The refrigerant sensor (50) detects a refrigerant leaking from the refrigerant circuit (R) in the container (1). Specifically, the refrigerant sensor (50) detects the refrigerant contained in the air flowing through the air passage (19) as an index. The refrigerant sensor (50) is disposed below the internal fan (30). Hereinafter, in some cases, the air containing the leaking refrigerant and the air not containing the leaking refrigerant are collectively referred to as air. Details of the refrigerant sensor (50) will be described later.

### (5) Notification Device

As illustrated in FIG. 4, the internal refrigeration apparatus (10) includes a notification unit or notification device or notifier (60). The notifier (60) is configured to notify the user of predetermined information. The notifier (60) includes a predetermined speaker or display. For example, when the circuitry (100) determines that there is an abnormality in the internal refrigeration apparatus (10) or the internal space (S), the notifier (60) issues a notification indicating that there is an abnormality from a speaker or displays the notification on a display.

### (6) Problem of Erroneous Detection by Refrigerant Sensor

When the property of the refrigerant (refrigerant gas) leaking into the internal space (S) and contained in the air flowing through the internal space (S) and the property of the miscellaneous gas generated in the internal space (S) are similar to each other, there is a risk that the refrigerant sensor (50) detects the miscellaneous gas as the refrigerant gas. For example, a non dispersive infraRed (NDIR) type sensor detects a specific gas by utilizing that various gases absorb a specific wavelength in an infrared region. In the NDIR type refrigerant sensor, in a case where the absorption wavelength region of the refrigerant gas and the absorption wavelength region of the miscellaneous gas overlap each other, or in a case where the absorption wavelength regions are relatively close to each other, there is a possibility that the refrigerant sensor cannot discriminate between the refrigerant gas and the miscellaneous gas, and detects the miscellaneous gas as the refrigerant gas.

Specifically, it is assumed that R1234yf and R32 are used as the refrigerant of the internal refrigeration apparatus, and a fruit that generates ethylene gas is stored in the internal space. Since the peak of the absorption wavelength of the refrigerant is around 3.3 μm and the ethylene gas also has a peak of the absorption wavelength in the vicinity thereof, in some cases, the NDIR type refrigerant sensor is not able to discriminatingly detect the ethylene gas generated from the fruit and the refrigerant gas leaking into the internal space by a combination of these gases.

On the other hand, the internal refrigeration apparatus (10) according to the present embodiment includes the first sensor (51) that detects an index different from a refrigerant. In other words, the first sensor (51) does not detect the refrigerant leaking into the internal space (S) which is an index detected by the refrigerant sensor (50). The internal refrigeration apparatus (10) according to the present embodiment determines refrigerant leakage in the internal space (S) based on a detection result of the refrigerant sensor (50) and a detection result of the first sensor (51). The first sensor (51) will be specifically described below.

The index of the present embodiment different from a refrigerant is a gas component in the internal space (S) other than the refrigerant. The first sensor (51) according to the present embodiment detects water vapor which is a gas component in the internal space (S). The first sensor (51) is a humidity sensor (51) that detects humidity in the internal space (S). The humidity may be either relative humidity or absolute humidity.

The humidity sensor (51) is disposed in the internal space (S). The humidity sensor (51) is disposed above the internal fan (30). The humidity sensor (51) is disposed on an air suction side of the internal fan (30).

Here, the humidity sensor (51) of the present embodiment is of the NDIR type. Since the peak of the absorption wavelength of water molecules is around 2.7μm, the absorption wavelength region of the infrared region of water molecules is different from the absorption wavelength region of the infrared region of the refrigerant (for example, R1234yf or R32). Therefore, the NDIR type humidity sensor (51) can suppress erroneous detection of a miscellaneous gas and water molecules.

For example, in a case where the humidity sensor (51) detects a behavior different from a usually assumed change in humidity such as a rapid decrease in humidity in the internal space, it can be estimated that the behavior is caused not by the humidity but by the refrigerant leaking into the internal space (S). As described above, the internal refrigeration apparatus (10) according to the present embodiment suppresses erroneous detection of the refrigerant by the refrigerant sensor (50) using the humidity sensor (51) having a property of hardly erroneously detecting other miscellaneous gas.

### (7) Operation of Circuitry

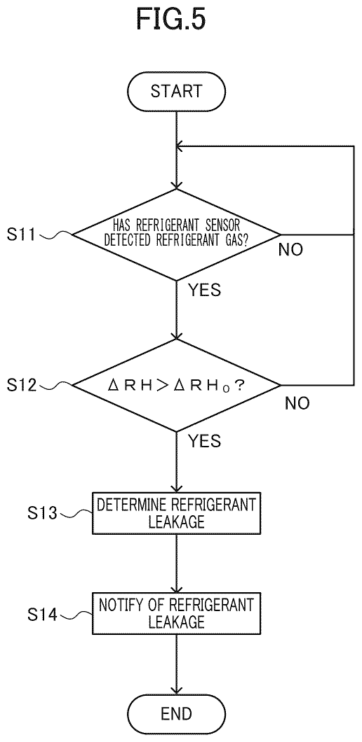

Hereinafter, operation of detection of refrigerant gas by the circuitry (100) will be described with reference to FIG. 5. The circuitry (100) is configured to determine refrigerant leakage in the internal space (S) based on detection results of the refrigerant sensor (50) and the humidity sensor (51). Note that, as the refrigerant, R1234yf is used.

In step S11, the circuitry (100) is configured to determine whether or not the refrigerant sensor (50) has detected a refrigerant gas. Specifically, the circuitry (100) is configured to determine whether or not a signal indicating detection of a refrigerant gas output from the refrigerant sensor (50) has been received. If it is determined that the refrigerant sensor (50) has detected a refrigerant gas (YES in step S11), step S12 is executed. If it is determined that the refrigerant sensor (50) has not detected the refrigerant gas (NO in step S11), step S11 is executed again.

In step S12, the circuitry (100) is configured to determine whether or not the humidity sensor (51) has detected that the degree of change in humidity is out of a predetermined range. Here, the degree of change in humidity indicates a degree ΔRH of decrease in humidity in the internal space (S) in a certain fixed period ΔT. For example, it is assumed that the fixed period ΔT is one minute, and a range in which the humidity normally assumed when the refrigerant does not leak into the internal space (S) in the one minute changes (decreases) is a predetermined range ΔRH₀. In a case where the humidity sensor (51) detects that the decrease in humidity (ΔRH) in the internal space (S) for one minute exceeds the predetermined range ΔRH₀, it can be estimated that the refrigerant gas has leaked into the internal space (S). For example, the ΔRH indicates a difference between the relative humidity RH₁ of a fixed period before (for example, one minute before) the present and the present relative humidity RH₂ (RH₂<RH₁).

The degree of change in humidity in the internal space (S) may be obtained by predetermined calculation. For example, the degree of change in humidity can be obtained using Combined Gas Law. Assuming that the air temperature and the relative humidity in the internal space (S) are 25 °C and 50%, respectively, a volume V_{R} (m³) corresponding to a refrigerant leakage amount (kg), a volume V (m³) of the housing space (3), a saturated water vapor amount RHₛ (g/m³) in the housing space (3) having an air temperature of 25 °C, and a water vapor amount RH₂₅ (g/m³) in the housing space (3) having an air temperature of 25 °C are set. At this time, for humidity RH when the refrigerant leaks into the internal space (S), a relation of RH=RH₂₅/RH_{S}×V/(V+V_{R}) (Formula 1) is satisfied. ΔRH in the fixed period ΔT can be obtained based on Formula 1.

The fixed period ΔT is arbitrarily set. The fixed period ΔT may be set based on the storage object stored in the internal space (S), or may be set based on the area where the container is installed, the season, or the transport route of the container. Based on the premise that the humidity change normally assumed is relatively gentle, the shorter the fixed period ΔT, the easier it is to distinguish between the change due to the humidity and the change due to the leaked refrigerant.

If it is determined that the degree ΔRH of change in humidity in the internal space (S) exceeds the predetermined range ΔRH₀ (YES in step S12), step S13 is executed. When it is not determined that the degree ΔRH of change in humidity of the internal space (S) exceeds the predetermined range ΔRH₀ (NO in step S12), it is determined that the refrigerant gas has not leaked into the internal space (S), and step S11 is executed again.

In step S13, the circuitry (100) is configured to determine that the refrigerant has leaked into the internal space (S). The circuitry (100) is configured to output, to the notifier (60), the fact that the refrigerant gas has leaked into the internal space (S).

In step S14, the circuitry (100) is configured to notify the user of the leakage of the refrigerant gas using the notifier (60) with an alarm or a display.

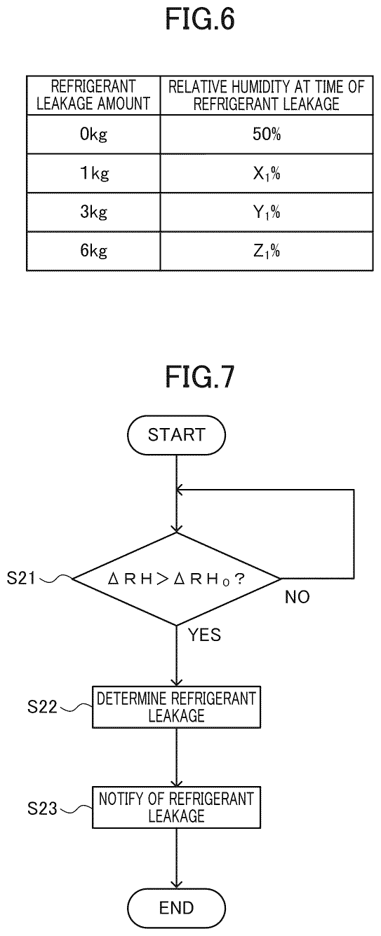

In addition, in the present embodiment, the amount of refrigerant leaking into the internal space (S) can be estimated based on the degree of change in humidity in the internal space (S). As illustrated in FIG. 6, assuming that the charging amount of the refrigerant in the internal refrigeration apparatus (10) is about 6 kg, when the leakage amount is 1 kg (leakage amount is 17% with respect to the charging amount of the refrigerant), when the leakage amount is 3 kg (leakage amount is 51% with respect to the charging amount of the refrigerant), and when the leakage amount is 6 kg (leakage amount is 100% with respect to the charging amount of the refrigerant), the relative humidity in the internal space (S) is individually set to X₁%, Y₁%, and Z₁% (50%>X₁>Y₁>Z₁). In a case where the humidity in the internal space (S) changes from 50% to X₁% in a certain fixed period, it can be estimated that 1 kg of the refrigerant leaks into the internal space (S). In a case where the humidity in the internal space (S) changes from 50% to Y₁% in a certain fixed period, it can be estimated that 3 kg of the refrigerant leaks into the internal space (S). In a case where the humidity in the internal space (S) changes from 50% to Z₁% in a certain fixed period, it can be estimated that 6 kg of the refrigerant leaks into the internal space (S).

### (8) Characteristics

### (8-1) Characteristics 1

The internal refrigeration apparatus (10) according to the present embodiment includes: the refrigerant sensor (50) that detects a refrigerant leaking into the internal space (S) of the container (1); the first sensor (51) that detects an index different from a refrigerant; and the circuitry (100) that is configured to determine refrigerant leakage in the internal space (S) based on detection results of the refrigerant sensor (50) and the first sensor (51).

While there is a risk that the refrigerant sensor (50) detects miscellaneous gas such as ethylene gas that may be generated in the internal space (S), in the present embodiment, the detection result of the first sensor (51) is used for the determination of refrigerant leakage in addition to the detection result of the refrigerant sensor (50). Accordingly, in a case where the refrigerant sensor (50) detects the refrigerant and the environmental change in the internal space (S) detected by the first sensor (51) is caused by refrigerant leakage, it can be determined that the refrigerant leaks into the internal space (S). As described above, erroneous detection of refrigerant leakage can be suppressed, and detection accuracy of refrigerant leakage can be improved.

### (8-2) Characteristics 2

The circuitry (100) of the internal refrigeration apparatus (10) according to the present embodiment is configured to determine refrigerant leakage in the internal space (S) in a case where the refrigerant sensor (50) detects refrigerant leakage and the first sensor (51) detects that a degree of change in concentration of a gas component in the internal space (S) is out of a predetermined range. Accordingly, the first sensor (51) can be used not only for determining a gas component in the internal space (S) but also for determining refrigerant leakage.

### (8-3) Characteristics 3

The first sensor (51) of the internal refrigeration apparatus (10) according to the present embodiment is a humidity sensor that detects humidity in the internal space (S). The humidity sensor (51) detects water vapor (water molecules) and hardly detects other miscellaneous gas. By using the humidity sensor (51) for the refrigerant leakage determination in this manner, the accuracy of the refrigerant leakage determination can be improved. In addition, the humidity sensor (51) is used for maintaining freshness (humidity management) of storage objects stored in the housing space (3) of the container (1). By using the humidity sensor (51) also for the refrigerant leakage determination in this manner, it is not necessary to newly provide a sensor only for the refrigerant leakage determination, and the number of components can be reduced.

### (9) Modification

Hereinafter, modifications of the above embodiment will be described. Hereinafter, a configuration different from that of the above embodiment will be described.

### (9-1) First Modification

In the first modification, the index that differs from that of the refrigerant is the pressure of the gas in the internal space (S). That is, the first sensor (51) of the first modification is a pressure sensor that detects the pressure of the gas in the internal space (S). When the refrigerant gas leaks into the internal space (S), the pressure of the gas in the internal space (S) increases by the amount of the leaking refrigerant gas. Using this point, circuitry (100) of the first modification is configured to determine the refrigerant leakage in the internal space (S) based on detection results of the refrigerant sensor (50) and the pressure sensor.

Specifically, in a case where the refrigerant sensor (50) detects refrigerant leakage and the pressure sensor detects that the degree of change in the pressure of the gas in the internal space (S) is out of a predetermined range, the circuitry (100) of the first modification is configured to determine refrigerant leakage in the internal space (S). Hereinafter, in some cases, the pressure of the air in the internal space (S) is referred to as an internal pressure.

The degree of change in the internal pressure indicates the degree of increase in the pressure of the gas in the internal space (S) in a certain fixed period ΔT. For example, it is assumed that the fixed period ΔT is one minute, and a range in which the internal pressure normally assumed when the refrigerant does not leak into the internal space (S) in the one minute decreases is a predetermined range ΔP₀. In a case where the pressure sensor detects that the degree ΔP of increase in the internal pressure in the internal space (S) in one minute exceeds the predetermined range ΔP₀, it is estimated that the refrigerant gas has leaked into the internal space (S). For example, the ΔP indicates a difference between the internal pressure P1 of a fixed period before (for example, one minute before) the present and the present internal pressure P2 (P2>P1).

The degree of change in the internal pressure may be obtained by predetermined calculation. For example, the degree of change in the internal pressure can be obtained using Combined Gas Law. Specifically, for internal pressure P1 due to refrigerant leakage, volume V1 of the internal space, standard atmospheric pressure P2 (1 atmospheric pressure), and volume V_{R} of the refrigerant leakage amount, a relation of P1=(V1+V_{R})×P2/V1 (Formula 2) is satisfied.

By substituting known values for V1 and P2 in Formula 2, the internal pressure P1 after refrigerant leakage can be obtained based on the volume V_{R} of the refrigerant leakage amount. As described above, in the first modification, the circuitry (100) is configured to determine whether or not the degree ΔP of change in internal pressure in the fixed period ΔT exceeds the predetermined range ΔP₀. The determination operation by the circuitry (100) corresponds to step S12 of the above embodiment.

In the first modification, the pressure sensor in the internal space (S) can be used for the refrigerant leakage determination. In addition, the amount of refrigerant leaking into the internal space (S) can be estimated based on the degree of change in the internal pressure. For example, assuming that the charging amount of the refrigerant in the internal refrigeration apparatus (10) is about 6 kg, when the leakage amount is 1 kg (the leakage amount is 17% with respect to the charging amount of the refrigerant), when the leakage amount is 3 kg (the leakage amount is 51% with respect to the charging amount of the refrigerant), and when the leakage amount is 6 kg (the leakage amount is 100% with respect to the charging amount of the refrigerant), the pressure in the internal space (S) is individually set to X₂kPa, Y₂kPa, and Z₂kPa (P2<X₂<Y₂<Z₂). When the internal pressure rises from P2 to X₂ within a certain fixed period, the amount of refrigerant leaking into the internal space (S) is found to be 1 kg. The same applies to Y₂ and Z₂.

### (9-2) Second Modification

An index of a second modification different from a refrigerant is a current value of the motor (30a) that drives the internal fan (30). That is, the first sensor (51) of the second modification is a current sensor that detects a current value of the motor (30a) that drives the internal fan (30). When the refrigerant leaks into the internal space (S), the density of the gas in the internal space (S) increases. Therefore, the operation load of the internal fan (30) increases, and the value of the current flowing through the motor (30a) increases. Using this point, in a case where the refrigerant sensor (50) detects refrigerant leakage and the current sensor detects that the degree of change in the current value of the motor (30a) is out of a predetermined range, the circuitry (100) according to the second modification is configured to determine refrigerant leakage in the internal space (S).

The degree of change in the current value indicates the degree of increase in the current value of the internal fan motor (30a) in a certain fixed period ΔT. For example, it is assumed that the fixed period ΔT is one minute, and a range in which the current value of the motor (30a) normally assumed when the refrigerant does not leak into the internal space (S) in the one minute increases is a predetermined range ΔE₀. In a case where the current sensor detects that the increase (ΔE) in the current value of the motor (30a) in the internal space (S) in one minute exceeds the predetermined range ΔE₀, it is estimated that the refrigerant gas has leaked into the internal space (S). For example, the ΔE indicates a difference between the current value E1 of a fixed period before (for example, one minute before) the present and the present current value E2 (E2>E1).

As described above, the circuitry (100) is configured to determine whether or not the degree ΔE of change in current value of the internal fan motor (30a) in the fixed period ΔT exceeds the predetermined range ΔE₀. The determination operation by the circuitry (100) corresponds to step S12 of the above embodiment.

As described above, in the second modification, the current sensor that detects the current value of the internal fan motor (30a) can be used for the refrigerant leakage determination. In addition, the current value of the motor (30a) may be set based on the amount of refrigerant gas leaking into the internal space (S). Accordingly, the amount of refrigerant leaking into the internal space (S) can be estimated by measuring the current value of the motor (30a).

### (9-3) Third Modification

In the third modification, the index that differs from that of the refrigerant is the pressure of the refrigerant flowing through the refrigerant circuit (R). That is, the first sensor (51) of the third modification is a refrigerant pressure sensor that detects the pressure of the refrigerant flowing through the refrigerant circuit (R). When the refrigerant leaks from a refrigerant pipe or the internal heat exchanger (29), the pressure of the refrigerant in the refrigerant circuit (R) decreases. Using this point, in a case where the refrigerant sensor (50) detects refrigerant leakage and the refrigerant pressure sensor detects that the degree of change in the pressure of the refrigerant flowing through the refrigerant circuit (R) is out of a predetermined range, the circuitry (100) of the third modification is configured to determine refrigerant leakage in the internal space (S). The position where the refrigerant pressure sensor is provided is not limited, but in the third modification, the refrigerant pressure sensor is provided in the refrigerant pipe in the refrigerant circuit (R).

The degree of change in the refrigerant pressure indicates the degree of decrease in the pressure of the refrigerant in the refrigerant circuit (R) in a certain fixed period ΔT. For example, it is assumed that the fixed period ΔT is one minute, and a range in which the refrigerant pressure of the refrigerant circuit (R) assumed when the refrigerant does not leak into the internal space (S) in the one minute decreases is a predetermined range ΔP_{R0}. In a case where the pressure sensor detects that the degree ΔP_{R} of decrease in the refrigerant pressure of the refrigerant circuit (R) in one minute exceeds the predetermined range ΔP_{R0}, it is estimated that the refrigerant gas has leaked into the internal space (S). For example, the ΔP_{R} indicates a difference between the refrigerant pressure P_{R1} of a fixed period before (for example, one minute before) the present and the present refrigerant pressure P_{R2} (P_{R2}<P_{R1}).

In this manner, the circuitry (100) is configured to determine whether or not the degree ΔP_{R} of change in the refrigerant pressure in the refrigerant circuit (R) in the fixed period ΔT exceeds the predetermined range ΔP_{R0}. The determination operation by the circuitry (100) corresponds to step S12 of the above embodiment.

As described above, in the third modification, the refrigerant pressure sensor can be used for determination of refrigerant leakage in the internal space (S). In addition, the value of the refrigerant pressure of the refrigerant circuit (R) may be set based on the amount of refrigerant gas leaking into the internal space (S). Accordingly, the amount of refrigerant leaking into the internal space (S) can be estimated by measuring the refrigerant pressure in the refrigerant circuit (R).

### (9-4) Fourth Modification

An internal refrigeration apparatus (10) according to a fourth modification does not include a refrigerant sensor (50) but includes a first sensor (51). That is, in the fourth modification, only the first sensor (51) detects the refrigerant leaking into the internal space (S). The first sensor (51) may be any one of the sensors of the above embodiment and the first to third modifications. It is assumed that the first sensor (51) of the fourth modification is a humidity sensor (51). In the fourth modification, only the humidity sensor (51) detects refrigerant leakage in the internal space (S). Operation of the circuitry (100) of the fourth modification will be described with reference to FIG. 7.

In step S21, the circuitry (100) is configured to determine whether or not the humidity sensor (51) has detected that the degree ΔRH of change in humidity in the internal space (S) is out of the predetermined range ΔRH₀. If it is determined that the degree ΔRH of decrease in humidity in the internal space (S) exceeds the predetermined range ΔRH₀ (YES in step S21), step S22 is executed. If it is determined that the degree ΔRH of decrease in humidity in the internal space (S) does not exceed the predetermined range ΔRH₀ (NO in step S21), step S21 is executed again. The degree ΔRH of change in humidity and the predetermined range ΔRH₀ are as described in the above embodiment.

In step S22, the circuitry (100) is configured to output, to the notifier (60), the fact that refrigerant gas is leaking into the internal space (S).

In step S23, the circuitry (100) is configured to notify the user of the leakage of the refrigerant gas using the notifier (60) with an alarm or a display.

As described above, since the absorption wavelength region of a miscellaneous gas such as ethylene gas in the infrared region is different from the absorption wavelength region of a water molecule, the humidity sensor (51) can suppress erroneous detection of the water molecule and the miscellaneous gas. Therefore, the refrigerant leaking into the internal space (S) can be detected by using the humidity sensor (51) without using the refrigerant sensor (50). Accordingly, the humidity sensor (51) can be used both for measuring the humidity in the internal space (S) and for detecting leaked refrigerant.

### (10) Other Embodiments

The above embodiment or each of the above modifications may have the following configuration.

The container (1) may be used not only for marine transportation but also for land transportation. In addition, a refrigeration storage (1) is not required to be a container. In some embodiments, the refrigeration storage (1) is a stationary cold storage warehouse installed on land.

The sensor type of the first sensor (51) is not limited. In some embodiments, the first sensor (51) is an NDIR type, a semiconductor type, or a thermal conductivity type. It is preferable that the first sensor (51) is not a sensor that causes erroneous detection (cross sensitivity) of a miscellaneous gas (such as ethylene gas) that may be generated in the internal space (S) other than the refrigerant gas.

In the above first modification, in some embodiments, the first sensor (51) that detects a gas component is an ethylene gas sensor that detects ethylene gas. In this case, the first sensor (51) is not an NDIR type sensor, and the refrigerant to be filled in the internal refrigeration apparatus (10) does not have to be a refrigerant (for example, R32, R1234yf) having a “—CH group” in the molecular structure. This is because since ethylene also has a “—CH group”, in the case of the NDIR type sensor, absorption wavelength regions of an ethylene gas having the same “—CH group” and a refrigerant gas (for example, R32, R1234yf) overlap with each other, and it is difficult to distinguish and detect the ethylene gas and the refrigerant gas, and the detection accuracy of the refrigerant gas cannot be improved. The ethylene gas sensor is used for management of a ripeness state of a fruit or a vegetable in a case where the storage object stored in the housing space (3) is the fruit or vegetable that generates ethylene gas such as a banana. As described above, by using the ethylene gas sensor also for determination of refrigerant leakage, it is not necessary to provide a new sensor for determining refrigerant leakage, and the number of components can be reduced.

In the above first modification, in some embodiments, the first sensor (51) is an oxygen sensor that detects oxygen in the internal space (S). The oxygen sensor is, for example, a semiconductor type. The oxygen concentration in the internal space (S) decreases according to the amount of refrigerant leaking into the internal space (S). Using this point, the circuitry (100) is configured to determine the refrigerant leakage in the internal space (S) based on detection results of the refrigerant sensor (50) and the oxygen sensor. Also in this case, the oxygen concentration (ppm) in the internal space (S) can be calculated according to the leakage amount (kg) of the refrigerant into the internal space (S) in accordance with the Combined Gas Law. Accordingly, based on the degree of decrease from the oxygen concentration in the internal space (S) or the oxygen concentration in the atmosphere, the leakage of the refrigerant can be determined and the leakage amount of the refrigerant can be determined. The oxygen sensor is provided, for example, in the container (1) including an adjustment device (not illustrated) that adjusts the composition of air in the internal space (S). The adjustment device adjusts the outside air to a predetermined composition, and supplies the adjusted air to the internal space (S). The adjustment device adjusts a composition of air in the housing space (3) in order to maintain freshness of storage objects (in particular, fruits and vegetables) stored in the housing space (3). The oxygen sensor is used to detect whether or not the oxygen concentration in the housing space (3) has reached the target concentration by the operation of the adjustment device, whether or not the oxygen concentration in the housing space (3) has returned to the atmospheric concentration after the adjustment device is stopped, and the like. By using such an oxygen sensor also for refrigerant leakage determination, it is not necessary to provide a new sensor for determining refrigerant leakage, and the number of components can be reduced.

In the above first modification, in some embodiments, the first sensor (51) is a carbon dioxide sensor that detects carbon dioxide in the internal space (S). The carbon dioxide sensor is, for example, an NDIR type. The concentration of carbon dioxide in the internal space (S) decreases according to the amount of refrigerant leaking into the internal space (S). Using this point, the circuitry (100) is configured to determine the refrigerant leakage in the internal space (S) based on detection results of the refrigerant sensor (50) and the carbon dioxide sensor. Also in this case, the carbon concentration (ppm) in the internal space (S) can be calculated according to the leakage amount (kg) of the refrigerant into the internal space (S) in accordance with the Combined Gas Law. Accordingly, based on the degree of decrease from the concentration of carbon dioxide in the internal space (S) or the concentration of carbon dioxide in the atmosphere, the leakage of the refrigerant can be determined, and the leakage amount of the refrigerant can be determined. The carbon dioxide sensor is provided, for example, in the container (1) including the adjustment device described above. By using such a carbon dioxide sensor also for determination of refrigerant leakage, it is not necessary to provide a new sensor for determining refrigerant leakage, and the number of components can be reduced.

In the above embodiment, in a case where the refrigerant sensor (50) detects refrigerant leakage and the first sensor (51) detects that the concentration of the gas in the internal space (S) is out of a predetermined range, the circuitry (100) may be configured to determine the refrigerant leakage in the internal space (S). The predetermined range indicates a normally assumed range of the concentration of gas in the internal space (S) in a case where the refrigerant does not leak. That is, in a case where the refrigerant sensor (50) detects refrigerant leakage and the concentration of gas in the internal space (S) exceeds a predetermined range, the refrigerant leakage in the internal space (S) may be determined.

In the above first modification, in a case where the refrigerant sensor (50) detects refrigerant leakage and the first sensor (51) detects that the pressure of gas in the internal space (S) is out of a predetermined range, the circuitry (100) may be configured to determine the refrigerant leakage in the internal space (S). The predetermined range indicates a normally assumed range of the internal pressure in the internal space (S) in a case where the refrigerant does not leak. That is, in a case where the refrigerant sensor (50) detects refrigerant leakage and the pressure of air in the internal space (S) exceeds a predetermined range, the refrigerant leakage in the internal space (S) may be determined.

In the above second modification, in a case where the refrigerant sensor (50) detects refrigerant leakage and the first sensor (51) detects that the current value of the motor (30a) is out of a predetermined range, the circuitry (100) may be configured to determine the refrigerant leakage in the internal space (S). The predetermined range indicates a normally assumed range of the current value of the motor (30a) in a case where the refrigerant does not leak. That is, in a case where the refrigerant sensor (50) detects refrigerant leakage and the current value of the motor (30a) exceeds a predetermined range, the refrigerant leakage in the internal space (S) may be determined.

In the above third modification, in a case where the refrigerant sensor (50) detects refrigerant leakage and the first sensor (51) detects that the pressure of the refrigerant flowing through the refrigerant circuit (R) is out of a predetermined range, the circuitry (100) may be configured to determine the refrigerant leakage in the internal space (S). The predetermined range indicates a normally assumed range of the refrigerant pressure in the refrigerant circuit (R) in a case where the refrigerant does not leak. That is, in a case where the refrigerant sensor (50) detects refrigerant leakage and the refrigerant pressure in the refrigerant circuit (R) exceeds a predetermined range, the refrigerant leakage in the internal space (S) may be determined.

In the above fourth modification, in a case where it is detected that the relative humidity in the internal space (S) is out of a predetermined range, the circuitry (100) may be configured to determine the refrigerant leakage in the internal space (S). The predetermined range indicates a normally assumed range of the humidity in the internal space (S) in a case where the refrigerant does not leak.

In the above third modification, in some embodiments, the first sensor (51) is a refrigerant temperature sensor that detects the temperature of a refrigerant flowing through the refrigerant circuit (R). Since the refrigerant pressure can be obtained based on the refrigerant temperature in the refrigerant circuit (R), it can be determined that the refrigerant gas is leaking from the refrigerant circuit (R) based on the degree of change in the refrigerant temperature or the refrigerant temperature. Specifically, in a case where the refrigerant sensor (50) detects refrigerant leakage and the refrigerant temperature sensor detects that a degree of change in the temperature of the refrigerant flowing through the refrigerant circuit (R) or a refrigerant temperature is out of a predetermined range, the circuitry (100) is configured to determine the refrigerant leakage in the internal space (S).

In the above third modification, in some embodiments, the first sensor (51) is a sensor that detects an index indicating the pressure or temperature of the refrigerant flowing through the refrigerant circuit (R).

In the above embodiment and each modification, the order of step S11 and step S12 may be reversed. That is, after the first sensor (51) detects that the above-mentioned change rate is out of a predetermined range in step S12 (YES in step S12), the refrigerant sensor (50) may determine detection of the refrigerant in step S11.

In the above embodiment and each modification, step S11 and step S12 may be performed simultaneously.

In the above embodiment and each modification, how to obtain the “degree of change” is not limited. In some embodiments, the degree of change indicates how much the value has changed from a certain reference value regardless of a fixed period. For example, in some cases, the degree of change is the change rate. The change rate indicates a rate of change with respect to a predetermined reference value. For example, in a case where the first sensor (51) is a humidity sensor, and when a reference value (for example, 50% RH) of the relative humidity of the internal space (S) is set as a reference humidity, and the relative humidity when the refrigerant leaks into the internal space (S) is set as a first humidity, the change rate can be defined as a ratio of the first humidity to the reference humidity. Since the value of the first humidity varies depending on the refrigerant leakage amount, the refrigerant leakage can be determined and the refrigerant leakage amount can also be estimated by obtaining such a change rate. In addition, in a case where the first sensor (51) is an oxygen sensor, the reference value of the oxygen concentration in the internal space (S) is the atmospheric oxygen concentration. In a case where the first sensor (51) is a carbon dioxide sensor, the reference value of the carbon dioxide concentration in the internal space (S) is the atmospheric carbon dioxide concentration.

In step S12 of the above embodiment, a plurality of fixed periods may be set. For example, it is assumed that the fixed period is set to 1 minute, 1.5 minutes, and 3 minutes. In a case where a different predetermined range ΔRH₀ is provided for each of the fixed periods and the degree ΔRH of humidity change in any one of the fixed periods is out of the predetermined range ΔRH₀, it may be determined as YES in step S12. By setting the plurality of predetermined periods as described above, the accuracy of the refrigerant leakage detection can be improved.

The internal space (S) only needs to be a space inside the container (1), and may be, for example, only the housing space (3).

The embodiments and the modifications have been described above, but it will be understood that various changes can be made to modes and details without departing from the spirit and the scope of the claims. The above embodiments and the modifications may be combined or replaced as appropriate as long as target functions of the present disclosure are not impaired. The above descriptions of “first”, “second”, . . . are used to distinguish words and phrases to which these descriptions are given, and the number and order of the words and phrases are not limited.

### INDUSTRIAL APPLICABILITY

As described above, the present disclosure is useful for the internal refrigeration apparatus and the refrigeration storage.

### REFERENCE SIGNS LIST

1 container (refrigeration storage)

10 internal refrigeration apparatus

30 internal fan

30a internal fan motor (motor)

50 refrigerant sensor

51 first sensor

100 circuitry

R refrigerant circuit

S internal space

1. An internal refrigeration apparatus configured to cool an internal space using a refrigerant circuit configured to perform a refrigeration cycle, the internal refrigeration apparatus comprising:
a refrigerant sensor configured to detect a refrigerant leaking into the internal space;
a first sensor configured to detect an index different from a refrigerant; and
circuitry configured to determine refrigerant leakage in the internal space based on detection results of the refrigerant sensor and the first sensor.

2. The internal refrigeration apparatus according to claim 1,
wherein the first sensor detects a gas component in the internal space, and
in a case where the refrigerant sensor detects refrigerant leakage and the first sensor detects that a concentration of a gas component in the internal space or a degree of a change in the concentration is out of a predetermined range, the circuitry is configured to determine refrigerant leakage in the internal space.

3. The internal refrigeration apparatus according to claim 1,
wherein the first sensor detects humidity, oxygen, or carbon dioxide in the internal space.

4. The internal refrigeration apparatus according to claim 1,
wherein the first sensor detects pressure of gas in the internal space, and
in a case where the refrigerant sensor detects refrigerant leakage and the first sensor detects that pressure of gas in the internal space or a degree of a change in the pressure is out of a predetermined range, the circuitry is configured to determine refrigerant leakage in the internal space.

5. The internal refrigeration apparatus according to claim 1, further comprising an internal fan configured to circulate air in the internal space,
wherein the first sensor detects a current value of a motor configured to drive the internal fan, and
in a case where the refrigerant sensor detects refrigerant leakage and the first sensor detects that a current value of the motor or a degree of a change in the current value is out of a predetermined range, the circuitry is configured to determine refrigerant leakage in the internal space.

6. The internal refrigeration apparatus according to claim 1,
wherein the first sensor detects pressure or temperature of a refrigerant flowing through the refrigerant circuit, and
in a case where the refrigerant sensor detects refrigerant leakage and the first sensor detects that an index indicating pressure or temperature of a refrigerant flowing through the refrigerant circuit or a degree of a change in the index is out of a predetermined range, the circuitry is configured to determine refrigerant leakage in the internal space.

7. A refrigeration storage comprising the internal refrigeration apparatus according to claim 1.

8. A method for controlling an internal refrigeration apparatus, the method comprising:
detecting, by a refrigerant sensor, a refrigerant leaking into an internal space;
detecting, by a first sensor, an index different from the refrigerant; and
determining, by circuitry, a refrigerant leakage in the internal space based on detection results from the refrigerant sensor and the first sensor.

9. The method of claim 8, wherein
the first sensor detects a gas component in the internal space, and
the determining, by the circuitry, the refrigerant leakage in the internal space further comprises the refrigerant sensor detecting the refrigerant leakage and the first sensor detecting that a concentration of a gas component in the internal space or a degree of a change in the concentration is out of a predetermined range.

10. The method of claim 8, wherein the first sensor detects humidity, oxygen, or carbon dioxide in the internal space.

11. The method of claim 8, wherein
the first sensor detects pressure of gas in the internal space, and
the determining, by the circuitry, the refrigerant leakage in the internal space further comprises the refrigerant sensor detecting the refrigerant leakage and the first sensor detecting that pressure of gas in the internal space or a degree of change in the pressure is out of a predetermined range.

12. The method of claim 8, further comprising
detecting, by the first sensor, a current value of a motor configured to drive an internal fan, wherein
the determining, by the circuitry, the refrigerant leaking in the internal space further comprises the refrigerant sensor detecting the refrigerant leakage and the first sensor detecting that the current value of the motor or a degree of change in the current value is out of a predetermined range.

13. The method of claim 8, wherein
the first sensor detects pressure or temperature of a refrigerant flowing through the refrigerant circuit, and
the determining, by the circuitry, the refrigerant leaking in the internal space further comprises the refrigerant sensor detecting the refrigerant leakage and the first sensor detecting that an index indicating pressure or temperature of a refrigerant flowing through the refrigerant circuit or a degree of a change in the index is out of a predetermined range.

14. The method of claim 8, further comprising outputting, by the circuitry, a notification to a notifier indicating the refrigerant leakage in the internal space.

15. A non-transitory computer-readable medium storing instructions that, when executed by circuitry of an internal refrigeration apparatus, cause the circuitry to perform operations comprising:
detecting, by a refrigerant sensor, a refrigerant leaking into an internal space;
detecting, by a first sensor, an index different from the refrigerant; and
determining, by circuitry, a refrigerant leakage in the internal space based on detection results from the refrigerant sensor and the first sensor.

16. The non-transitory computer-readable medium according to claim 15, wherein
the first sensor detects a gas component in the internal space, and
the determining, by the circuitry, the refrigerant leakage in the internal space further comprises the refrigerant sensor detecting the refrigerant leakage and the first sensor detecting that a concentration of a gas component in the internal space or a degree of a change in the concentration is out of a predetermined range.

17. The non-transitory computer-readable medium according to claim 15, wherein the first sensor detects humidity, oxygen, or carbon dioxide in the internal space.

18. The non-transitory computer-readable medium according to claim 15, wherein
the first sensor detects pressure of gas in the internal space, and
the determining, by the circuitry, the refrigerant leakage in the internal space further comprises the refrigerant sensor detecting the refrigerant leakage and the first sensor detecting that pressure of gas in the internal space or a degree of change in the pressure is out of a predetermined range.

19. The non-transitory computer-readable medium according to claim 15, wherein the operations further comprise:
detecting, by the first sensor, a current value of a motor configured to drive an internal fan, wherein
the determining, by the circuitry, the refrigerant leaking in the internal space further comprises the refrigerant sensor detecting the refrigerant leakage and the first sensor detecting that the current value of the motor or a degree of change in the current value is out of a predetermined range.

20. The non-transitory computer-readable medium according to claim 15, wherein
the first sensor detects pressure or temperature of a refrigerant flowing through the refrigerant circuit, and
the determining, by the circuitry, the refrigerant leaking in the internal space further comprises the refrigerant sensor detecting the refrigerant leakage and the first sensor detecting that an index indicating pressure or temperature of a refrigerant flowing through the refrigerant circuit or a degree of a change in the index is out of a predetermined range.
